(19) United States
(12) Patent Application Publication
(10) Pub. No.: US 2021/0335895 A1
(43) Pub. Date: Oct. 28, 2021

(54) TOUCH DISPLAY PANEL AND ELECTRONIC DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Xiaoliang FENG, Wuhan, Hubei (CN)

(73) Assignee: Wuhan China Star Optoelectronics Semiconductor Display Technology Co., Ltd., Wuhan, Hubei (CN)

(21) Appl. No.: 16/615,233

(22) PCT Filed: May 17, 2019
(86) PCT No.: PCT/CN2019/087438

§ 371 Date: Nov. 20, 2019

(30) Foreign Application Priority Data
Apr. 25, 2019 (CN) 201910340721.X

(51) Int. Cl. H01L 27/32; G06F 3/041

(52) U.S. Cl. CPC H01L 27/323; G06F 3/0412

(57) ABSTRACT

A touch display panel and an electronic device are disclosed. The touch display panel includes a base substrate; an organic light-emitting display layer disposed on the base substrate; an encapsulation layer disposed on the organic light-emitting display layer; a touch-control layer disposed on the encapsulation layer and comprising a plurality of first electrodes and a plurality of second electrodes staggered with respect to the first electrodes and insulated from the first electrodes; and a color filter layer disposed on the touch-control layer and comprising a black matrix and a plurality of color filter resists.

### BACKGROUND OF INVENTION

### 1. Field of Invention

The present invention relates to a display field, and particularly, to a touch display panel and an electronic device.

### 2. Related Art

Organic light-emitting diode (OLED) has been regarded as a next generation novel display technology due to advantages of being light in weight, wind viewing angles, quick response times, low temperature resistance, and high luminous efficiency.

Current touch display panels generally include display panels and touch panels. Display panels generally include organic light-emitting display layers and color filter layers. However, such a structure is configured with display panels and touch panels both manufactured separately, wherein the display panels need to be laminated to the touch panels through adhesive layers, resulting in an increase in thickness of the display panels.

Therefore, it is imperative to provide a touch display panel and an electronic device to overcome problems existing in current technology.

### SUMMARY OF INVENTION

An object of the present invention is to provide a touch display panel and an electronic device, capable of reducing a thickness of a display panel.

To achieve the above-mentioned object, the present invention provides a touch display panel, comprising a base substrate; an organic light-emitting display layer disposed on the base substrate; an encapsulation layer disposed on the organic light-emitting display layer; a touch-control layer disposed on the encapsulation layer and comprising a plurality of first electrodes and a plurality of second electrodes staggered with respect to the first electrodes and insulated from the first electrodes; and a color filter layer disposed on the touch-control layer and comprising a black matrix and a plurality of color filter resists.

The present invention further provides an electronic device comprising the above-mentioned touch display panel.

A touch display panel and an electronic device of the present invention include an organic light-emitting display layer, an encapsulation layer, a touch-control layer, and a color filter layer all sequentially disposed on a base substrate. Since the touch-control layer is directly disposed between the organic light-emitting display layer and the color filter layer, no glue is required for lamination, thereby reducing an overall thickness of the display panel.

### BRIEF DESCRIPTION OF DRAWINGS

FIG. 1 is a schematic structural view of a touch display panel of the present invention.

FIG. 2 is an enlarged schematic structural view of first electrodes and second electrodes of the present invention.

FIG. 3 is a schematic structural view of a touch-control layer of the present invention.

FIG. 4 is a top plan view of a color filter layer of the present invention.

### DESCRIPTION OF PREFERRED EMBODIMENTS

Hereafter, embodiments of the present invention will be described in detail with reference to the accompanying drawings, wherein same or like reference numerals designate same or like elements or elements having same or like functions throughout the specification. The embodiments described with reference to the accompanying drawings are to be regarded as illustrative to only explain the present invention, but not to be construed as limiting the present invention.

In the description of the present invention, it is to be understood that the term “center”, “longitudinal”, “lateral”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise” and the like indicates orientation or the orientation or positional relationship based on the positional relationship shown in the drawings, for convenience of description only and the present invention is to simplify the description, but does not indicate or imply that the device or element referred to must have a particular orientation in a particular orientation construction and operation, and therefore not be construed as limiting the present invention. In addition, the terms “first”, “second” are used to indicate or imply relative importance or the number of technical features specified implicitly indicated the purpose of description and should not be understood. Thus, there is defined “first”, “second” features may be explicitly or implicitly including one or more of the features. In the description of the new practice, the meaning of “plurality” is at least two, e.g. two, three, etc., unless explicitly specifically limited.

In the present invention, unless otherwise explicitly specified or limited, the terms “mounted”, “connected”, “connected”, “fixed” and like terms are to be broadly understood, for example, may be a fixed connection, may be is detachably connected to, or integrally; may be a mechanical connector, may be electrically connected; may be directly connected, can also be connected indirectly through intervening structures, it may be interaction between the two internal communicating elements or two elements. Those of ordinary skill in the art, to be understood that the specific meanings in the present invention in accordance with specific circumstances.

In the present invention, unless otherwise expressly specified or limited, the first feature being “on” or “lower” the second feature may include direct contact of the first and the second features and may also include that the first and the second features are not in direct contact, but in contact by the additional features therebetween. Also, the first feature being “on”, “above”, “upper” the second feature may include that the first feature is obliquely upward, directly above the second feature, or simply represent that a level of the first feature is higher than that of the second feature. The first feature being “beneath”, “below” and “lower” the second feature may include that the first feature is obliquely downward and right below the second feature, or simply represent that a level of the first feature is less than that of the second feature.

The following disclosure provides many different embodiments or examples to achieve different structures of the present invention. To simplify the disclosure of the present invention, the components and configuration of specific examples are described hereinafter. Of course, they are only illustrative, and are not intended to limit the present invention. Further, the present disclosure may repeat reference numerals in different embodiments and/or the reference letters. This repetition is for the purpose of simplicity and clarity, and does not indicate a relationship between the various embodiments and/or set in question. Further, the present invention provides various specific examples of materials and processes, but one of ordinary skill in the art may be appreciated that other processes and applications and/or other materials.

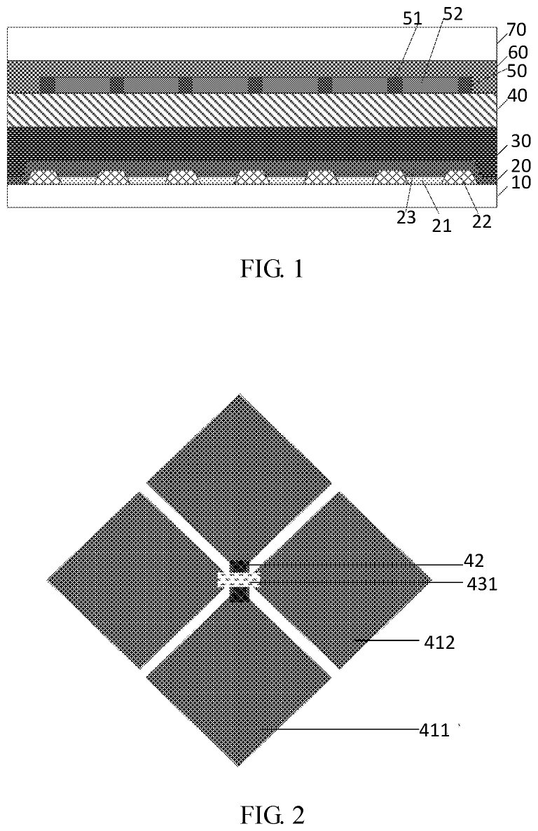

Please refer to FIGS. 1 to 4. FIG. 1 is a schematic structural view of a touch display panel of the present invention.

The touch display panel of the present invention includes a base substrate 10, an organic light-emitting display layer 20, an encapsulation layer 30, a touch-control layer 40, and a color filter layer 50. Furthermore, the touch display panel may also include a protective layer 60 and a glass cover 70.

The base substrate 10 includes a substrate and a switch array layer disposed on the substrate. The substrate may be a glass substrate or a flexible substrate. The switch array layer includes a plurality of thin-film transistors.

The organic light-emitting display layer 20 is disposed on the base substrate 10. The organic light-emitting display layer 20 includes an anode (not shown), an organic light-emitting layer 21, and a cathode 23, wherein the organic light-emitting layer 21 is formed by an evaporation process. Furthermore, the organic light-emitting display layer 20 may include a pixel defining layer 22. The pixel defining layer 22 includes a plurality of pixel defining units spaced apart from each other, wherein the organic light-emitting display layer 21 is located at a gap between two of the pixel defining units. The anode is connected to a drain of the thin-film transistor. The anode is made of indium tin oxide (ITO). The organic light-emitting display layer 20 includes a plurality of organic light-emitting units at a top plan view angle. A color of light emitted by the organic light-emitting units is white.

The encapsulation layer 30 is disposed on the organic light-emitting display layer 20. The encapsulation layer 30 includes a first inorganic layer, an organic layer, and a second inorganic layer, wherein the first inorganic layer and the second inorganic layer are configured to block moisture and oxygen. The organic layer is configured to buffer stress from inorganic layers to enhance flexibility of an OLED panel. A preparation process of the first inorganic layer is one or at least a combination of plasma enhanced chemical vapor deposition (PECVD), atomic layer deposition (ALD), and pulse laser deposition (PLD). The first inorganic layer is made of at least one of silicon nitride, silicon oxide, silicon carbide, silicon carbonitride, aluminum oxide, and the like. The organic layer is made of at least one of an epoxy resin, a silicon-based polymer, and polymethyl methacrylate. The second inorganic layer may be made of a material the same as that of the first inorganic layer.

Please further refer to FIG. 2. The touch-control layer 40 is disposed on the encapsulation layer 30 and includes a plurality of first electrodes 411 and a plurality of second electrodes 412 staggered with respect to and insulated from the first electrodes 411, wherein a process temperature of the touch-control layer 40 is less than 90 degrees. Since a heat resistant temperature of an OLED layer material is generally low, damage to the organic light-emitting display layer can be prevented when the touch-control layer 40 is formed through a low temperature process, wherein the touch-control layer 40 may be formed by a low temperature resistant material, for example, a heat resistance temperature of the material of the touch-control layer 40 is less than 90 degrees. Since the touch-control layer is made of a material compatible with the low temperature process, sensitivity of the touch-control layer can be improved, thereby improving accuracy and sensitivity of a touch function.

Adjacent two of the first electrodes 411 are electrically connected, and adjacent two of the second electrodes 412 are connected by a connecting bridge 431. In one embodiment, the first electrodes 411 are transmitting electrodes, and the second electrodes 412 are receiving electrodes.

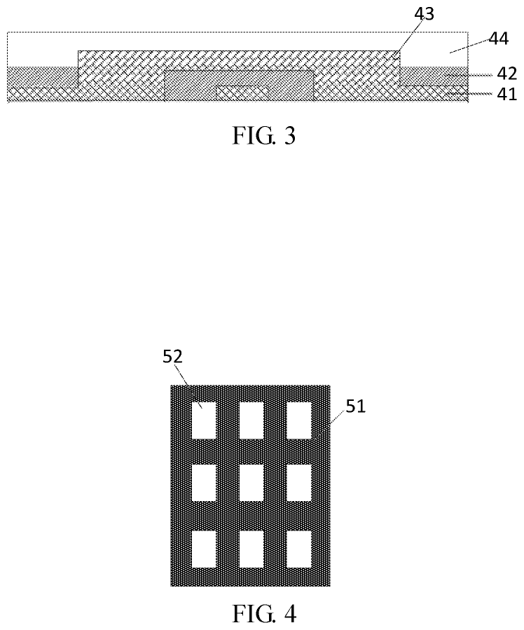

Please further refer to FIG. 3. The touch-control layer 40 has a cross-sectional structure including a first electrically conductive layer 41, an insulating layer 42, and a second electrically conductive layer 43, and further including a planarization layer 44.

The first electrically conductive layer 41 includes the first electrodes 411 and the second electrodes 412. That is, the first electrodes 411 and the second electrodes 412 are disposed on the first electrically conductive layer 41, wherein the first electrically conductive layer 41 is made of ITO.

The insulating layer 42 is disposed on the first electrically conductive layer 41 and is configured to separate the first electrically conductive layer 41 and the second electrically conductive layer 43.

The second electrically conductive layer 43 includes a plurality of connecting bridges 431. That is, the connecting bridges 431 are disposed on the second electrically conductive layer 43. In one embodiment, the second electrically conductive layer 43 is disposed on the first electrically conductive layer 42.

The planarization layer 44 is disposed above a top of the touch-control layer 40. For example, the planarization 44 is disposed on the second electrically conductive layer 43 and is made of an organic material.

In can be understood that in another embodiment, the second electrically conductive layer 43 is disposed below the first electrically conductive layer 41. In this manner, the planarization layer 44 is disposed on the first electrically conductive layer 41.

Please further refer to FIG. 4. The color filter layer 50 is disposed on the touch-control layer 40 and includes a black matrix 51 and a plurality of color filter resists 52. The black matrix 51 surrounds peripheries of the color filter resists 52, wherein the color filter resists 52 include a red color filter, a green color filter, and a blue color filter. A process temperature of the color filter layer 50 is less than 90 degrees

Please refer back to FIG. 1. The protective layer 60 is disposed on the color filter layer 50. In order to improve a lifespan and display performance of a display panel, the protective layer 60 is made of an organic insulating material. In order to prevent damage to the organic light-emitting display layer, a process temperature of the protective layer 60 is less than 90 degrees. That is, the protective layer 60 is fabricated by a low temperature process.

The glass cover 70 is disposed on the protective layer 60.

Since the touch-control layer is directly disposed between the organic light-emitting display layer and the color filter layer, no glue is required to bond the organic light-emitting display layer and the color filter layer, thereby reducing an overall thickness of the display panel. Therefore, a thickness of the touch display panel at the end is reduced to at least one-half of a conventional touch display panel. In addition, since the touch-control layer is directly disposed between the organic light-emitting display layer and the color filter layer, manufacturing processes can be simplified, thereby reducing production cost. Furthermore, since the touch-control layer and the color filter layer are formed by using a low temperature process, damage to the organic light-emitting layer can be avoided, so that a lifespan of the display panel is extended.

The present invention further provides an electronic device, including the above-mentioned touch display panel. The electronic device may be a device such as a mobile phone or a tablet computer.

A touch display panel and an electronic device of the present invention include an organic light-emitting display layer, an encapsulation layer, a touch-control layer, and a color filter layer all sequentially disposed on a base substrate. Since the touch-control layer is directly disposed between the organic light-emitting display layer and the color filter layer, no glue is required for lamination, thereby reducing an overall thickness of the display panel.

Accordingly, although the present invention has been disclosed as a preferred embodiment, it is not intended to limit the present invention. Those skilled in the art without departing from the spirit and scope of the present invention may make various changes or modifications, and thus the scope of the present invention should be after the appended claims and their equivalents.

1. A touch display panel, comprising:
a base substrate;
an organic light-emitting display layer disposed on the base substrate;
an encapsulation layer disposed on the organic light-emitting display layer;
a touch-control layer disposed on the encapsulation layer and comprising a plurality of first electrodes and a plurality of second electrodes staggered with respect to the first electrodes and insulated from the first electrodes; and
a color filter layer disposed on the touch-control layer and comprising a black matrix and a plurality of color filter resists.

2. The touch display panel of claim 1, wherein touch display panel further comprises a protective layer disposed on the color filter layer, and a glass cover disposed on the protective layer.

3. The touch display panel of claim 2, wherein the protective layer is made of an organic insulating material.

4. The touch display panel of claim 2, wherein a process temperature of the protective layer is less than 90 degrees.

5. The touch display panel of claim 1, wherein process temperatures of the touch-control layer and the color filter layer are both less than 90 degrees.

6. The touch display panel of claim 1, wherein the touch-control layer has a cross-sectional structure comprising:
a first electrically conductive layer comprising the plurality of first electrodes and the plurality of second electrodes;
an insulating layer disposed on the first electrically conductive layer; and
a second electrically conductive layer comprising a plurality of connecting bridges.

7. The touch display panel of claim 6, wherein the cross-sectional structure of the touch-control layer further comprises a planarization layer disposed above a top of the touch-control layer.

8. The touch display panel of claim 7, wherein the planarization layer is made of an organic material.

9. The touch display panel of claim 6, wherein the second electrically conductive layer is disposed on the first electrically conductive layer.

10. The touch display panel of claim 1, wherein the touch-control layer is made of a low temperature resistant material.

11. An electronic device, comprising a touch display panel comprising:
a base substrate;
an organic light-emitting display layer disposed on the base substrate;
an encapsulation layer disposed on the organic light-emitting display layer;
a touch-control layer disposed on the encapsulation layer and comprising a plurality of first electrodes and a plurality of second electrodes staggered with respect to the first electrodes and insulated from the first electrodes; and
a color filter layer disposed on the touch-control layer and comprising a black matrix and a plurality of color filter resists.

12. The electronic device of claim 11, wherein touch display panel further comprises a protective layer disposed on the color filter layer, and a glass cover disposed on the protective layer.

13. The electronic device of claim 12, wherein the protective layer is made of an organic insulating material.

14. The electronic device of claim 12, wherein a process temperature of the protective layer is less than 90 degrees.

15. The electronic device of claim 11, wherein process temperatures of the touch-control layer and the color filter layer are both less than 90 degrees.

16. The electronic device of claim 11, wherein the touch-control layer has a cross-sectional structure comprising:
a first electrically conductive layer comprising the plurality of first electrodes and the plurality of second electrodes;
an insulating layer disposed on the first electrically conductive layer; and
a second electrically conductive layer comprising a plurality of connecting bridges.

17. The electronic device of claim 16, wherein the cross-sectional structure of the touch-control layer further comprises a planarization layer disposed above a top of the touch-control layer.

18. The electronic device of claim 17, wherein the planarization layer is made of an organic material.

19. The electronic device of claim 16, wherein the second electrically conductive layer is disposed on the first electrically conductive layer.

20. The electronic device of claim 11, wherein the touch-control layer is made of a low temperature resistant material.
